(19) United States
(12) Patent Application Publication
(10) Pub. No.: US 2013/0200760 A1
(43) Pub. Date: Aug. 8, 2013

(54) KITCHEN MODULE

(71) Applicant: Hadi Teherani, Hamburg (DE)

(72) Inventor: Hadi Teherani, Hamburg (DE)

(73) Assignee: POGGENPOHL MÖBELWERKE GmbH, Herford (DE)

(21) Appl. No.: 13/638,635

(22) PCT Filed: Mar. 31, 2011
(86) PCT No.: PCT/EP2011/001644

§ 371 Date: Mar. 20, 2013

(30) Foreign Application Priority Data
Mar. 31, 2010 (DE) 10 2010 013 768.5

(51) Int. Cl. A47B 47/00; H05K 5/02

(52) U.S. Cl. CPC A47B 47/0091; H05K 5/0247
USPC 312/111; 312/223.6

(57) ABSTRACT

A kitchen module (10), especially for integration into a fitted kitchen, includes two cabinet elements (12,14), one of them being a first cabinet element (12) to be positioned at the wall (16) of a room, while the second cabinet element (14) is positioned in a free standing manner in front of the first cabinet element (12), and a passage (20) is remaining between the two cabinet elements (12,14), and a box shaped bridge element (26) connects the upper parts of the cabinet elements (12,14) and bridges the passage (20).

The present invention is related to a kitchen module, in particular to be integrated into fitted kitchens, according to the preamble of claim 1.

Kitchen installations exist in a large variety of designs that make it possible to adapt the kitchen individually to the needs of its users. For example, fitted kitchens can be assembled from different kitchen modules that may comprise cupboard elements like upper cupboards or floor cupboards, as well as tall cupboards, and moreover they can be provided to comprise electric devices.

It is an important object of kitchen design to combine an attractive appearance with a user friendly design. However, this does not always lead to satisfying results. For example, it is not always possible to provide short ways from one working place to another in the usual kitchen lines. Another problem that has not been solved yet lies in the desire to design an open kitchen, i. e. a kitchen that is an integrated part of the living space, but on the other hand the working area should be protected so that it cannot be watched from all areas from the living space.

Another problem in planning and installing the kitchen is the arrangement of electric cables for the lighting installation. Moreover, the kitchen modules shall provide much storing room for stock and inventory.

It is therefore an object of the present invention to provide a kitchen module of the above kind that solves foregoing problems and satisfies the needs of user with respect to ergonomics and required space.

This object is solved by a kitchen module comprising features of claim 1.

The kitchen module according to the present invention comprises two cabinet elements, namely a first cabinet element to be positioned at a wall of the room and a second free standing cabinet element. Between these cabinet elements there is a passage. The two cabinet elements are connected by a box shaped bridge element that bridges the passage.

This bridge element can be installed, for example, at the room ceiling and comprises its own body that provides storing space for kitchen inventory. The free height below the bridge element is provided such that a person can easily stand below it. The passage stays accessible from both sides, but it is screened by the free standing cabinet element so that the passage cannot be seen from any position in the room. Consequently the free standing cabinet element provides some visual protection that does not interfere with the open design of the kitchen module. Thus an open kitchen concept is possible that provides a protected working space at the same time.

The bridge element can be formed as one part with a first and/or the second cabinet element. The bottom of the bridge element forms a ceiling area of the passage that can be provided with luminous elements. The electric connections of this illumination can be installed within the body of the bridge element. The same is true for the supply cables of electric devices that can be installed within the free standing cabinet element, for example, a fridge, an oven, a monitor or anything else. Therefore the bridge element according to the present invention provides a simple solution for the problem to install the supply cables for electric devices in free standing cabinet elements.

Preferred embodiments of the present invention are subject of the subclaims.

According to one preferred embodiment of the present invention, the bridge element is intended to be positioned at a ceiling of the wall.

According to another embodiment, the bridge element is provided with storage compartments at its sides.

These storage compartments can be open or closed by doors that make it possible to close the storing space.

Preferably the bridge element is provided with lighting devices.

These lighting devices can be arranged in the bottom of the bridge element, i. e. in the ceiling of the passage, and supplied via cables that run within the bridge element towards an electric connection.

Preferably the second cabinet element is provided with a tall cupboard, whose inner space is accessible from the passage as well as from the opposed side of the cabinet element.

According to another preferred embodiment, the first cabinet element is provided as an upper cupboard.

According to another preferred embodiment, said kitchen module comprises a workable box shaped floor element that extends within the passage between the lower parts of the cabinet element.

This floor element is elevated above the level of the floor so that a step must be overcome to enter the passage. The floor element can be an additional design element of the kitchen module, but it can take similar functions as the bridge element. For example, electric wires can be also be installed within the floor element, or storage space can be provided within the floor element.

In the following a preferred embodiment of the present invention is explained with reference to the accompanied drawings.

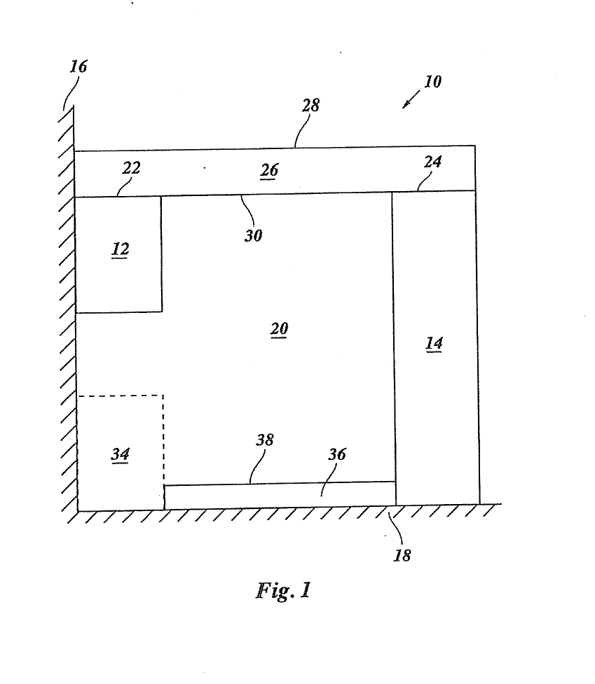

FIG. 1 is a schematic side view of one embodiment of the present invention; and

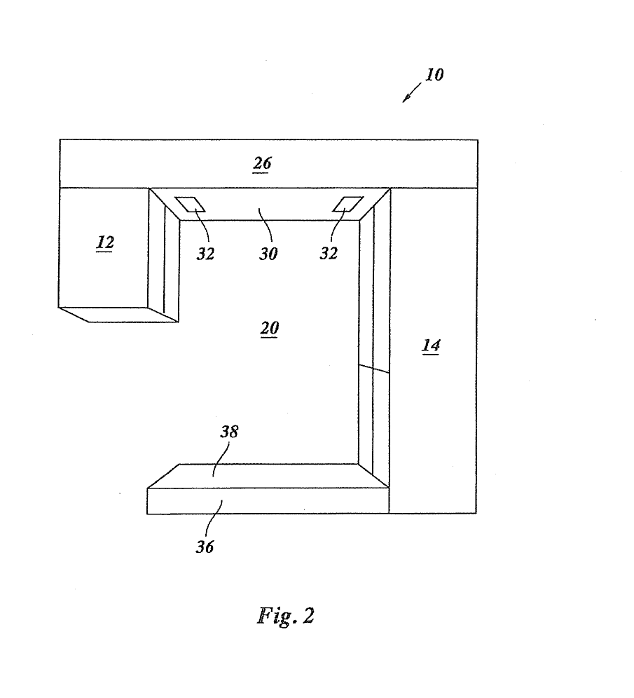

FIG. 2 is a perspective side view of the kitchen module from FIG. 1.

The kitchen module 10 in FIG. 1 comprises an upper cupboard 12 as a first cabinet element and a tall cupboard 14 as a second cabinet element. The upper cupboard 12 is hung to a wall 16 of the kitchen, as usual. The tall cupboard 14 stands free in front of the upper cupboard 12 on the kitchen floor 18. Between the upper cupboard 12 and the tall cupboard 14 remains a free space 20 as a passage. The upper cupboard 12 ins mounted in such a height that its upper side 22 is on the same level as the upper side 24 of the tall cupboard 14.

On the upper cupboard 12 and the tall cupboard 14, there lies a bridge element 26 that connects the upper parts of the cabinet elements 12,14 and bridges the passage 20. The bridge element 26 lies on the upper sides 22,24 of the cabinet elements 12,14 and extends from the kitchen wall 16 to the opposed outer edge of the tall cupboard 14. The bridge element 26 therefore limits the height of the passage 20, but in a way that a person can stand upright within the passage 20. The upper side 28 of the bridge element 26 has a distance to the ceiling of the room. Unlike shown in the present embodiment, the bridge element 26 can also be mounted to the room ceiling.

The opening of the cupboard doors of the upper cupboard 12 and the tall cupboard 14 is not obstructed by the bridge element 26, so that all parts of the cupboards are freely accessible. The bridge element 26 has a box shaped form and comprises its own furniture body that is provided with storage space for kitchen inventory or other items at its sides. In this way the bridge element 26 provides additional storing space in the kitchen. The body of the bridge element 26 can also be connected in another way to the cabinet elements 12,14 than it is shown here. For example, it is possible that the side plates of the cabinet elements 12,14 extend up to the upper edge 28 of the bridge element 26, and an intermediate part of the bridge element 26 is formed within the passage 20 by another side plate element. In the mounted state, both cabinet elements 12,14 form one unit together with the bridge element 26.

In the bottom 30 of the bridge element 26, forming the ceiling of the passage 20, lighting devices 32 (also see FIG. 2) are integrated that are provided for lighting the passage 20. Electric supply cables for the lighting devices 32 extend through the bridge element 26 to the kitchen wall 16, where an electric socket is provided. Thus the bridge element 26 provides covered cable installations for lighting devices that can be optionally provided in the upper cupboard 12 or in the tall cupboard 14. Moreover, the tall cupboard 145 can be provided to receive an electric installed device like a fridge, an electric oven or the like. Also for such devices, the electric supply cables can be guided within the bridge element 26 over the passage 20 to the kitchen wall 16. Therefore the bridge element 26 provides a possibility to facilitate the cable supply to electric devices that are arranged within free standing cabinet elements that have no other connection to the room wall where the electric sockets are usually provided.

Below the upper cupboard 12, a floor cupboard 34 can be arranged. Its position is shown schematically in FIG. 1. Between such a floor cupboard 34 and the tall cupboard 14, a box shaped floor element 36 may extend, its upper side 38 being elevated over the floor 18. For entering the passage 20, a step must be passed. The box shaped floor element 36 can be constructed in a similar way as a bridge element 26, i. e. it may have its own furniture body that is connected to the lower parts of the tall cupboard 14 and the floor cupboard 34. The floor element 36 can also be used to comprise the electric supply cables for the lighting devices or installed electric devices received within the tall cupboard 14.

Within the scope of the present invention, different embodiments of the kitchen module 10 can be realized. For example, the cabinet element mounted to the kitchen wall 16 can be provided as a tall cupboard that extends from the kitchen floor 18 can be provided as a tall cupboard that extends from the kitchen floor 18 up to the bottom side of the bridge element 26. Moreover, the tall cupboard 14 can be accessed from the passage 20 as well as from the opposite free side and it may comprise cupboard doors at its opposing sides. Within the kitchen module 10, a space is provided within the passage 20 that cannot be visible from the remaining space in the kitchen because the tall cupboard 14 provides some visual protection. However, because the passage 20 is open to both sides, an open concept of the kitchen is still provided. Moreover, the bridge element 26 provides additional storing space without taking additional mounting space in the kitchen.

FIG. 2 shows a perspective view of the kitchen module 10 described above, in which the floor 18, the kitchen wall 16 and an optionally provided floor cupboard 34 below the upper cupboard 12 are not shown.

What is claimed is:

1. Kitchen module for integration into a fitted kitchen, comprising:
a first cabinet element adapted to be positioned at a wall of a room,
a second cabinet element positioned in a free standing manner in front of the first cabinet element,
a passage between the two cabinet elements, and
a box-shaped bridge element connecting upper parts of the cabinet elements and bridging the passage.

2. Kitchen module according to claim 1, wherein said bridge element is adapted to be positioned at a ceiling of the wall.

3. Kitchen module according to claim 1, wherein said bridge element includes storage compartments at sides thereof.

4. Kitchen module according to claim 1, wherein the bridge element includes lighting devices.

5. Kitchen module according to claim 1, wherein the second cabinet element is provided as tall cupboard, with an inner space that is accessible from the passage as well as from an opposed side of the second cabinet element.

6. Kitchen module according to claim 1, further comprising:
an electric device that is built into the second cabinet element, and
electric supply cables for supplying electric current to the electric device, said electric cables being guided through the bridge element.

7. Kitchen module according to claim 1, wherein the first cabinet element is provided as an upper cupboard.

8. Kitchen module according to claim 1, further comprising a workable box shaped floor element that extends within the passage between lower parts of the cabinet elements.
